(19) United States
(12) Patent Application Publication
(10) Pub. No.: US 2010/0283135 A1
(43) Pub. Date: Nov. 11, 2010

(54) LEAD FRAME FOR SEMICONDUCTOR DEVICE

(75) Inventors: Jinzhong YAO, Tianjin (CN); Zhigang Bai, Tianjin (CN); Junhua Luo, Tianjin (CN); Meijiang Song, Tianjin (CN); Hong Zhu, Tianjin (CN)

Correspondence Address: ONDA TECHNO Intl. Patent Attys., 12-1 Omiya-cho 2-chome, Gifu City, 500-8731, JP

(73) Assignee: FREESCALE SEMICONDUCTOR, INC, Austin, TX (US)

(21) Appl. No.: 12/753,118

(22) Filed: Apr. 2, 2010

(30) Foreign Application Priority Data
May 8, 2009 (CN) 200910140565.9

(51) Int. Cl. H01L 23/495; H01L 23/00

(52) U.S. Cl. 257/676; 257/692; 257/E23.031; 257/E23.002

(57) ABSTRACT

A lead frame including a lead frame structure having a die support area and a plurality of electrical contact areas has shallow recesses formed on a surface of the lead frame structure.

### BACKGROUND OF THE INVENTION

The present invention relates to the packaging of integrated circuits (ICs) and more particularly to lead frames for semiconductor packages.

Delamination of a molding compound from a lead frame of a semiconductor package is undesirable as it can cause package failure. Failure mechanisms that can result from lead frame delamination include bond lifting, heel cracking, and broken wires. Lead frame delamination can also lead to package cracking. Thus, it would be desirable to have a lead frame that can reduce the incidence of lead frame delamination.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is a schematic top plan view of a lead frame in accordance with an embodiment of the present invention;

FIG. 2 is an enlarged cross-sectional view of a portion of the lead frame of FIG. 1 along a line X-X;

FIG. 3 is a schematic top plan cut-away view of a semiconductor package in accordance with another embodiment of the present invention; and

FIG. 4 is an enlarged cross-sectional view of a portion of a lead frame along a line Y-Y in FIG. 3.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a lead frame including a lead frame structure having a die support area and a plurality of electrical contact areas. In one embodiment, a shallow recess is formed on a surface of the lead frame structure. In another embodiment, a plurality of shallow recesses is formed on a surface of the lead frame structure at least partially around respective ones of a plurality of critical portions of the lead frame structure. In yet another embodiment, a shallow recess is formed on a surface of the lead frame structure. An integrated circuit (IC) die is attached to the die support area and electrically connected to the electrical contact areas. The IC die and a portion of the lead frame structure are encapsulated with a molding compound.

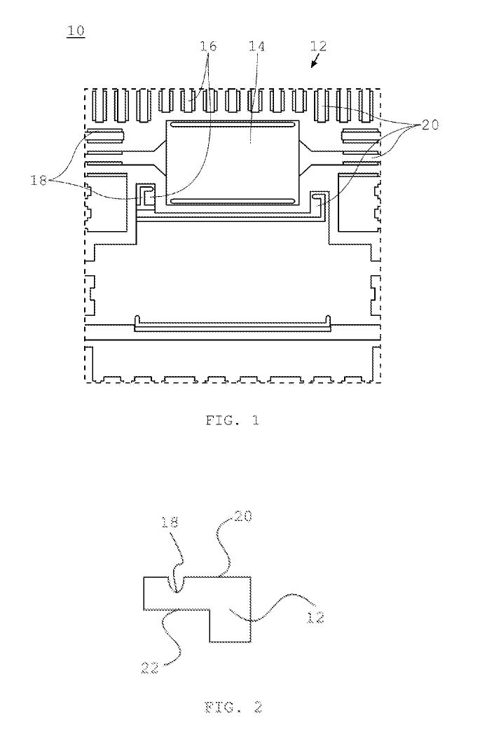

Referring now to FIG. 1, a schematic top plan view of a lead frame 10 is shown. The lead frame 10 includes a lead frame structure 12 having a die support area 14 and a plurality of electrical contact areas 16. A plurality of shallow recesses 18 is formed on a surface of the lead frame structure 12 at least partially around respective ones of a plurality of critical portions 20 of the lead frame structure 12.

The lead frame 10 may be formed from a copper or metal alloy sheet or strip via etching or stamping, as is known in the art. The lead frame 10 may have a thickness of between about 120 microns (μm) and about 770 μm, and may be plated with a metal or metal alloy. The die support area 14 is sized and shaped to receive an integrated circuit (IC) die. The die, and consequently the die support area 14, size may vary depending on the function of the circuitry therein. As will be understood by those of skill in the art, the invention is not limited by the size and shape of the die support area 14. The electrical contact areas 16, also sometimes referred to as lead fingers, are generally situated around the perimeter of the lead frame 10, or along one or more sides of the lead frame 10. As can be seen in FIG. 1, the length of the electrical contact areas 16 may vary. For example, the electrical contact areas 16 closest or adjacent to the die support area 14 may be shorter than the electrical contact areas that are further away from the die support area 14. However, in other embodiments, the electrical contact areas 16 could be of uniform length.

Referring now to FIG. 2, an enlarged cross-sectional view of a portion of the lead frame 10 along a line X-X in FIG. 1 is shown. As shown in FIG. 2, the shallow recess 18 is formed as a groove in the critical portion 20 of the lead frame structure 12.

The provision of shallow recesses 18 on a surface of the lead frame structure 12 increases the contact area between the lead frame 10 and encapsulation material that is subsequently deposited thereon. The increase in contact area helps to improve adhesion between the lead frame 10 and the encapsulation material. Additionally, the shallow recesses 18 help to contain any initial delamination between the lead frame 10 and the encapsulation material.

The shallow recesses 18 may be formed to a depth of between about 15 percent (%) and about 30% of a thickness of the lead frame structure 12, and more preferably to a depth of between about 20% and about 25% of the thickness of the lead frame structure 12. For example, the shallow recesses 18 may be formed to a depth of between about 100 microns (μm) and about 130 μm in a lead frame structure 12 having a thickness of about 510 μm.

The shallow recesses 18 may have a width of between about 0.1 millimeter (mm) and about 0.25 mm. Advantageously, the narrowness of the widths of the shallow recesses 18 relative to the surface area of particular portions 20 of the lead frame 10 in which the shallow recesses 18 are formed allows flexibility in the layout of the shallow recesses 18. For example, the shallow recesses 18 are not limited to a straight trench design, but may be formed of different shapes. The narrowness of the widths of the shallow recesses 18 also allows the shallow recesses 18 to be positioned in small critical areas of the lead frame 10.

In one embodiment, the shallow recesses 18 may be formed by etching using an etch mask. The depth of the shallow recesses 18 may be controlled by varying the aperture width of the etch mask. The aperture width of the etch mask is reduced to achieve a shallower etching depth. The shallow recesses 18 also may be formed by laser cutting, punching or other known lead frame manufacturing processes in alternative embodiments.

As shown in FIG. 2, the shallow recesses 18 may be formed over and on an opposite surface to an etched portion 22 of the lead frame structure 12. This is possible due to the shallowness of the recesses 18 relative to the thickness of the lead frame 10. The shallow recess 18 and the half-etched portion 22 may be formed simultaneously.

Although FIG. 2 shows the shallow recess 18 formed on one (1) surface of the lead frame structure 12 and over the half-etched portion 22, it will be understood that shallow recesses 18 may be formed on both surfaces of the lead frame structure 12 and, furthermore, at the same location on the lead frame structure 12.

Referring again to FIG. 1, the critical portions 20 include one or more of a die bonding area (i.e., the die support area 14), a wire bonding area (i.e., the electrical contact areas 16), a moisture sensitive area such as, for example, a tie-bar area, and other areas of the lead frame structure 12 where lead frame delamination can affect package performance. The provision of shallow recesses 18 at least partially around the critical portions 20 helps to prevent penetration of delamination into critical areas of the semiconductor package, thereby improving package robustness.

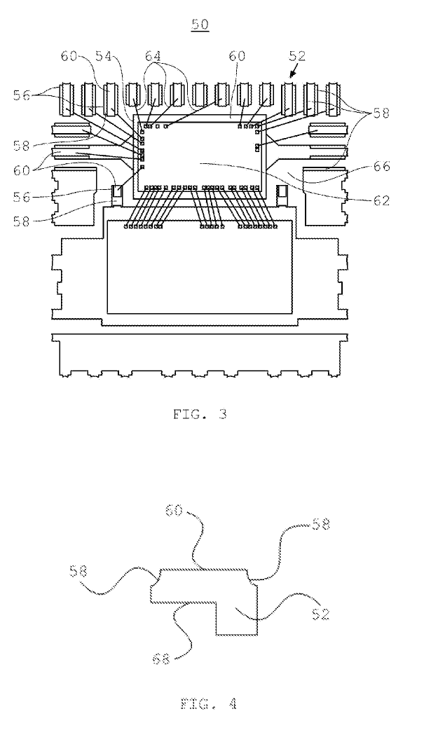

Referring now to FIG. 3, a schematic top plan cut-away view of a semiconductor package 50 is shown. The semiconductor package 50 includes a lead frame structure 52 having a die support area 54 and a plurality of electrical contact areas 56. A plurality of shallow recesses 58 is formed on a surface of the lead frame structure 52 at least partially around respective ones of a plurality of critical portions 60 of the lead frame structure 52. An integrated circuit (IC) die 62 is attached to the die support area 54 and is electrically connected to the electrical contact areas 56 via a plurality of wires 64. The IC die 62 and a portion of the lead frame structure 52 are encapsulated by a molding compound 66.

The semiconductor package 50 may be a power quad flat no-lead (PQFN) package or any other package type that requires a lead frame.

The lead frame structure 52 is similar to the lead frame structure 12 of FIGS. 1 and 2, except that the shallow recesses 58 of the present embodiment are laid out differently. Accordingly, detailed description of similar elements will be omitted. However, the difference in layout is described below.

Referring now to FIG. 4, an enlarged cross-sectional view of a critical portion 60 of the lead frame structure 52 along a line Y-Y in FIG. 3 is shown. As shown in FIG. 4, the shallow recesses 58 are formed as steps at an edge of the critical portion 60 in the present embodiment. As shown also in FIG. 4, one of the shallow recesses 58 is formed over and on an opposite surface to a half-etched portion 68 of the lead frame structure 52.

Referring again to FIG. 3, the IC die 62 may be any type of circuit such as, for example, a digital signal processor (DSP) or a special function circuit. The IC die 62 is not limited to a particular technology such as CMOS, or derived from any particular wafer technology. Further, the present invention can accommodate IC dice of various sizes; for example, in one embodiment, the IC die 62 may be about 3 mm by about 5 mm in size.

The wires 64 may be made of gold (Au), copper (Cu), aluminum (Al) or other electrically conductive materials as are known in the art and commercially available. A known wire bonding process may be used to form the electrical connections.

A well known encapsulation process such as, for example, injection molding, may be performed to encapsulate the IC die 62 and the wires 64. The molding compound 66 may comprise a well known commercially available molding material such as plastic or epoxy.

As can be seen from FIGS. 1 and 3, the shallow recesses 18 and 58 are not limited to a straight trench design. Rather, the shallow recesses 18 and 58 are shaped according to the critical area they are intended to protect.

As is evident from the foregoing discussion, the present invention provides a lead frame and a semiconductor package with improved mold compound locking and delamination stopping features in the form of shallow recesses on a surface of the lead frame structure. Because of their small dimensions, the shallow recesses may be formed in critical areas of the lead frame where space is a constraint. Accordingly, the present invention is able to provide improved delamination protection to critical areas of a lead frame.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. A lead frame, comprising:
a lead frame structure having a die support area and a plurality of electrical contact areas, wherein a shallow recess is formed on a surface of the lead frame structure.

2. The lead frame of claim 1, wherein the shallow recess is formed at least partially around a critical portion of the lead frame structure.

3. The lead frame of claim 2, wherein the critical portion comprises at least one of a die bonding area, a wire bonding area, and a moisture sensitive area.

4. The lead frame of claim 2, wherein the shallow recess is formed as a step at an edge of the critical portion.

5. The lead frame of claim 1, wherein the shallow recess is formed to a depth of between about 15 percent (%) and about 30% of a thickness of the lead frame structure.

6. The lead frame of claim 5, wherein the shallow recess is formed to a depth of between about 20% and about 25% of the thickness of the lead frame structure.

7. The lead frame of claim 1, wherein the shallow recess is formed over and on an opposite surface to an etched portion of the lead frame structure.

8. The lead frame of claim 1, wherein the shallow recess has a width of between about 0.1 millimeter (mm) and about 0.25 mm.

9. A lead frame, comprising:
a lead frame structure having a die support area and a plurality of electrical contact areas, wherein a plurality of shallow recesses is formed on a surface of the lead frame structure at least partially around respective ones of a plurality of critical portions of the lead frame structure.

10. The lead frame of claim 9, wherein the critical portions comprise one or more of a die bonding area, a wire bonding area, and a moisture sensitive area.

11. The lead frame of claim 9, wherein the shallow recesses are formed to a depth of between about 15% and about 30% of a thickness of the lead frame structure.

12. The lead frame of claim 11, wherein the shallow recesses are formed to a depth of between about 20% and about 25% of the thickness of the lead frame structure.

13. A semiconductor package, comprising:
a lead frame structure having a die support area and a plurality of electrical contact areas, wherein a shallow recess is formed on a surface of the lead frame structure;
an integrated circuit (IC) die attached to the die support area and electrically connected to the electrical contact areas; and
a molding compound encapsulating the IC die and a portion of the lead frame structure.

14. The semiconductor package of claim 13, wherein the shallow recess is formed at least partially around a critical portion of the lead frame structure.

15. The semiconductor package of claim 14, wherein the critical portion comprises one of a die bonding area, a wire bonding area, and a moisture sensitive area.

16. The semiconductor package of claim 14, wherein the shallow recess is formed as a step at an edge of the critical portion.

17. The semiconductor package of claim 13, wherein the shallow recess is formed to a depth of between about 15% and about 30% of a thickness of the lead frame structure.

18. The semiconductor package of claim 17, wherein the shallow recess is formed to a depth of between about 20% and about 25% of the thickness of the lead frame structure.

19. The semiconductor package of claim 13, wherein the shallow recess is formed over and on an opposite surface to a half-etched portion of the lead frame structure.

20. The semiconductor package of claim 13, wherein the shallow recess has a width of between about 0.1 millimeter (mm) and about 0.25 mm.
